(19) United States
(12) Patent Application Publication
(10) Pub. No.: US 2004/0027179 A1
(43) Pub. Date: Feb. 12, 2004

(54) Dual mode data output buffers and methods of operating the same

(76) Inventor: Seong-Jin Jang, Kyounggi-do (KR)

Correspondence Address: MYERS BIGEL SIBLEY & SAJOVEC, PO BOX 37428, RALEIGH, NC, 27627, US

(21) Appl. No.: 10/446,317

(22) Filed: May 28, 2003

(30) Foreign Application Priority Data
Aug. 9, 2002 (KR) 2002-47067

(51) Int. Cl. H03B 1/00

(52) U.S. Cl. 327/112

(57) ABSTRACT

A dual mode data output buffer includes first and second drivers configured to output data responsive to first and second data output signals, respectively. A transmission gate is also provided. The transmission gate is configured to select between a first mode of operation and a second mode of operation responsive to a mode control signal. The transmission gate provide the second data output signal to the second driver when the mode control signal is not asserted during the first mode of operation and the transmission gate provides a modified second data output signal when the mode control signal is asserted during the second mode of operation.

### RELATED APPLICATION

This application is related to and claims priority from Korean Patent Application No. 2002-47067 filed Aug. 9, 2002, the disclosure of which is hereby incorporated herein by reference as if set forth in its entirety.

### FIELD OF THE INVENTION

The present invention relates to integrated circuit devices and methods of operating the same and, more particularly, to data output buffers and methods of operating the same.

### BACKGROUND OF THE INVENTION

Generally, integrated circuit memory devices are classified in one of two categories, static random access memories (SRAMs) and dynamic random access memories (DRAMs). A unit memory cell of a DRAM typically has a simpler stricture than a unit memory cell of an SRAM. Accordingly, the DRAM structure may have advantages over the SRAM structure when used in high-density integrated circuit devices. To improve the speed of read and/or write operations, the DRAM may operate synchronously with a system clock of, for example, a computer, in which the DRAM is disposed. DRAMs that operate synchronously with the system clock may be termed synchronous dynamic random access memories (SDRAMs). The S-DRAM may synchronize to the system clock so that it may receive a command for a row operation and/or a data read/write operation. Furthermore, various commands for performing functions of the S-DRAM may be input and/or output synchronously with the system clock. For example, data may be input and/or output at a leading edge and/or a trailing edge of the system clock.

In the S-DRAM, signals received from outside of a chip may be synchronized with the system clock. An internal circuit may be divided into synchronous and asynchronous portions with respect to the system clock. The synchronous portion may be further subdivided into a portion synchronizing to a system clock received from outside the chip and a portion synchronizing to an internal clock generated inside the chip. For example, operations of row address decoding, activation of selected word lines and bit line sensing do not typically synchronize to the clock. On the other hand, data input/output operations of an integrated circuit memory device typically synchronize to the clock.

Integrated circuit memory devices may have data output buffers for outputting a logic state of data while reading data stored in memory cells. Conventional data output buffers may include a push-pull data output buffer for a voltage mode open drain channel and an open drain data output buffer for a current mode open drain channel.

Referring now to FIG. 1, a conventional push-pull data output buffer for a voltage mode open drain channel will be discussed. As illustrated in FIG. 1, a data output buffer 100 may be provided in a memory, a transmission path 12 may also be provided for transmitting the data output from the data output buffer 100, and a controller 200 may be provided for receiving the output data over the transmission path 12 and for performing other operations known to those of skill in the art.

As illustrated in FIG. 1, the controller 200 includes a positive-channel metal oxide semiconductor (PMOS) transistor 10. The PMOS transistor 10 includes a gate, a source and a drain. The gate of the PMOS transistor 10 is coupled to ground, the source of the PMOS transistor 10 is coupled to a voltage source V_{T}, and the drain of the PMOS transistor 10 is coupled to the transmission path 12 to match the characteristic impedance of the transmission path 12.

As further illustrated in FIG. 1, the data output buffer 100 includes a PMOS transistor 14 and a negative-channel metal oxide semiconductor (NMOS) transistor 16, connected in series between a voltage source (V_{CC}) and ground, for example, V_{SS}. The PMOS transistor 14 and the NMOS transistor 16 are turned on and output data when receiving first and second data output signals OutP and OutN, respectively. A drain of the PMOS transistor 14 is coupled to a drain of the NMOS transistor 16. An input/output node 50 provided between the PMOS transistor 14 and the NMOS transistor 16 and is coupled with the transmission path 12.

The gate of the PMOS transistor 10 is coupled to ground, thus, the PMOS transistor 10 is typically turned on. The PMOS transistor 10 may be designed with an adjustment such that a reciprocal number of transconductance (gm) may be the same as an impedance Zₒ. When the PMOS transistor 10 is turned on, the voltage source V_{T} is applied to the transmission path 12. The first and second data output signals OutP and OutN are applied to gates of the PMOS transistor 14 and the NMOS transistor 16, respectively. When the first and second data output signals OutP and OutN are set to a logic high and applied to the gates of the PMOS transistor 14 and the NMOS transistor 16, respectively, the PMOS transistor 14 is turned off and the NMOS transistor 16 is turned on. Accordingly, a logic low signal is applied to the transmission path 12. On the other hand, when first and second data output signals OutP and OutN are set to a logic low and are applied to the gates of the PMOS transistor 14 and the NMOS transistor 16, the PMOS transistor 14 is turned on, the NMOS transistor 16 is turned off, and a logic high signal is applied to the transmission path 12.

Referring now to FIG. 2, a conventional current mode drain channel data output buffer will be discussed. As illustrated in FIG. 2, a data output buffer 300 is provided in a memory for storing data, a transmission path 22 is also provided for transmitting the data output from the data output buffer 300, and a controller 400 is provided for receiving the output data applied through the transmission path 22 and for performing other operations known to those of skill in the art.

The controller 400 includes a PMOS transistor 20 having a gate, a source and a drain. The gate of the PMOS transistor 20 is coupled to ground, the source of the PMOS transistor 20 is coupled to a voltage source V_{T}, and the drain of the PMOS transistor 20 is coupled to a transmission path 22 to match the characteristic impedance of the transmission path 22.

The data output buffer 300 includes first and second NMOS transistors 24, 26, connected in series between the transmission path 22 and ground and is configured to be turned on and output data when a data output signal Out and a bias voltage V_{bias} are received through respective gates thereof. A source of the NMOS transistor 24 is coupled with a drain of the NMOS transistor 26, and a source of the NMOS transistor 26 is coupled to ground.

The gate of the PMOS transistor 20 is also coupled to ground, thus the PMOS transistor 20 is typically turned on. The PMOS transistor 20 is designed with an adjustment size so that a reciprocal number of a transconductance (gm) is same as an impedance Zo. When the PMOS transistor 20 is turned on, the voltage source V_{T} is applied to the transmission path 22. As the bias voltage V_{bias} is applied to the gate of the NMOS transistor 26, the NMOS transistor 26 is turned on. Furthermore, a data output signal is applied to the gate of the NMOS transistor 24. When the data output signal Out is set to a logic low level and is applied to the gate of the NMOS transistor 24, the NMOS transistor 24 is turned off, and a logic high signal is output onto the transmission path 22. On the other hand, when the data output signal Out is set to a logic high level and is applied to the gate of the NMOS transistor 24, the NMOS transistor 24 is turned on, and a logic low signal is output onto the transmission path 22.

Conventional integrated circuit memory devices typically include both types of data output buffers, i.e. push-pull and open drain, which are separately designed and separately disposed in the integrated circuit memory device. Accordingly, the size of the integrated circuit device including both types of data output buffers may be increased and additional expenses may be incurred.

### SUMMARY OF THE INVENTION

Embodiments of the present invention provide a dual mode data output buffer including first and second drivers configured to output data responsive to first and second data output signals, respectively. A transmission gate is also provided. The transmission gate is configured to select between a first mode of operation and a second mode of operation responsive to a mode control signal. The transmission gate provides the second data output signal to the second driver when the mode control signal is not asserted during the first mode of operation and the transmission gate provides a modified second data output signal to the second driver when the mode control signal is asserted during the second mode of operation.

In some embodiments of the present invention the transmission gate includes a first transistor that is responsive to a first electrical reference and the second data output signal and a second transistor that is responsive to the mode control signal and the second data output signal. The first electrical reference may be set to a logic high level during the first and second modes of operation. The mode control signal may be set to a logic low level during the first mode of operation and set to a logic high level during the second mode of operation.

In further embodiments of the present invention the second data output signal may be set to V_{CC} during the second mode of operation and may be applied to the transmission gate. The transmission gate may transmit the second data output signal (V_{CC}) decreased by a threshold voltage (Vₜₕ) to the second driver. In certain embodiments of the present invention, the first driver may include a PMOS transistor and the second driver may include an NMOS transistor.

In still further embodiments of the present invention the first data output signal may be set to a logic high level during the second mode of operation and the dual mode data output buffer may provide a logic low signal to a controller over a transmission line. Alternatively, the first data output signal may be set to a logic low level during the second mode of operation and the dual mode data output buffer may provide a logic high signal to a controller over a transmission line.

In some embodiments of the present invention the first transistor may include an NMOS transistor and the second transistor may include a PMOS transistor. The first and second output control signals may be set to a logic high level, the first driver may be turned off and the second driver may be turned on during the first mode of operation. The dual mode data output buffer may provide a logic low signal to a controller over a transmission line. Alternatively, the first and second output control signals may be set to a logic low level, the first driver may be turned on during and the second driver may be turned off during the second mode of operation. The dual mode data output buffer may provide a logic high signal to a controller over a transmission line.

In further embodiments of the present invention first and second channels of the first and second drivers, respectively, may be connected in series between a first electrical reference and a second electrical reference. The first mode of operation may be a push-pull mode and the second mode of operation may be an open drain mode. The mode control signal may include a mode register set signal, a fusing signal and/or an electrical reference.

While the present invention is described above primarily with reference to data output buffers, methods of operating data output buffers are also provided.

### BRIEF DESCRIPTION OF THE DRAWINGS

FIG. 1 is a circuit diagram illustrating conventional push-pull voltage mode open drain output buffers;

FIG. 2 is a circuit diagram illustrating conventional current mode open drain channel output buffers;

FIG. 3 is a circuit diagram illustrating dual mode data output buffers according to embodiments of the present invention; and

FIG. 4 is a voltage waveform illustrating operations of the dual mode data output buffer during a second mode of operation, i.e., an open drain mode, in a saturation region according to embodiments of the present invention.

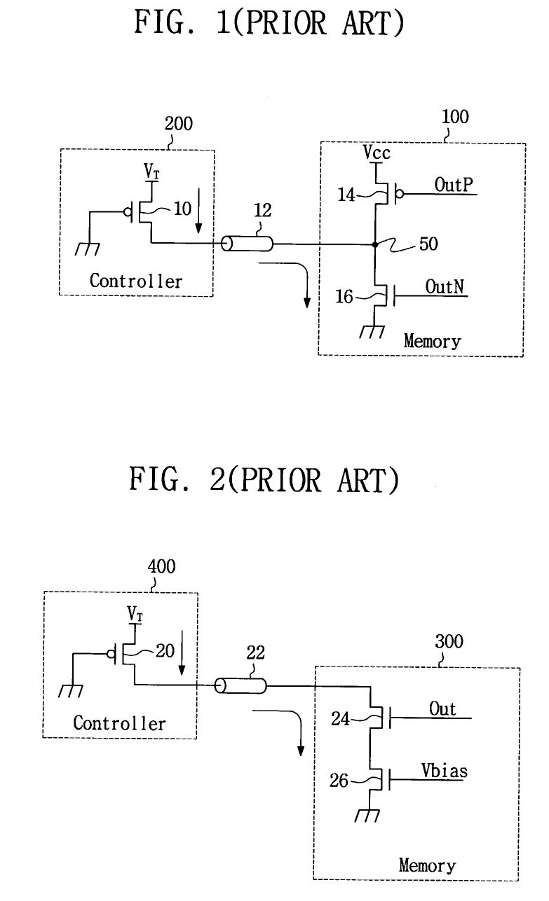

### DETAILED DESCRIPTION OF EMBODIMENTS OF THE PRESENT INVENTION

The present invention now will be described more fully with reference to the accompanying drawings, in which embodiments of the invention are shown. This invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like reference numerals refer to like elements throughout.

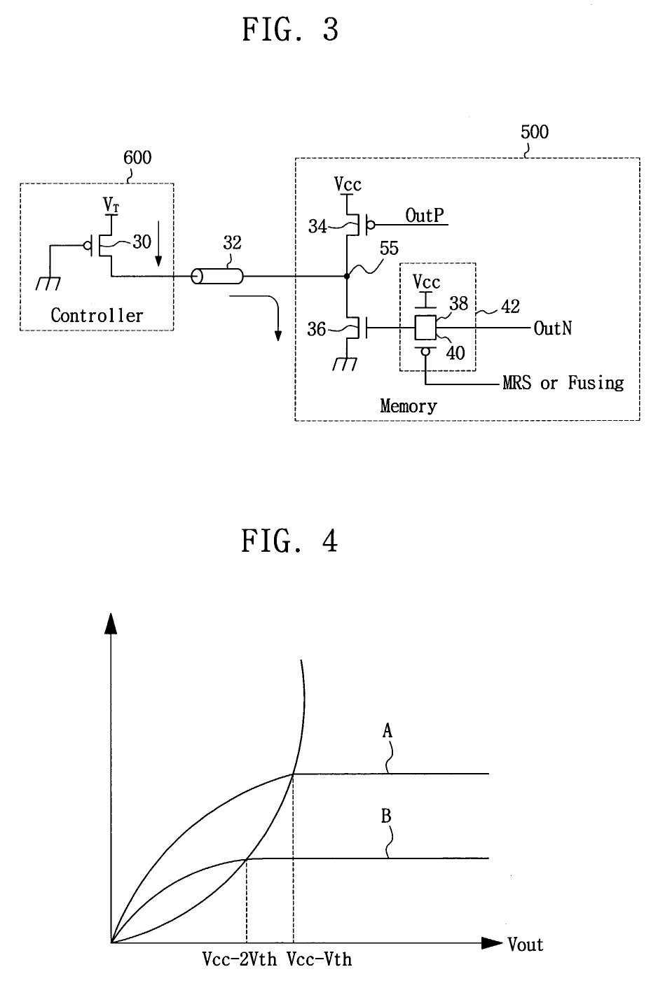

Embodiments of the present invention will be described below with respect to FIGS. 3 and 4. Embodiments of the present invention provide dual mode data output buffers that may be included in, for example, integrated circuit memory devices, that combine the functionality of push-pull data output buffers and open drain output buffers into a single dual mode data output buffer. Accordingly, the size and cost of an integrated circuit devices including dual mode data buffers according to embodiments of the present invention may be reduced.

Referring now to FIG. 3, dual mode data output buffers according to embodiments of the present invention will be discussed. As illustrated in FIG. 3, a data output buffer 500 for storing data may be included in, for example, an integrated circuit memory device. A transmission path 32 may be provided for transmitting data output from the dual mode data output buffer 500 and a controller 600 may be provided for receiving the output data through the transmission path 32 and for performing other operations known to those having skill in the art.

The controller 600 may include a PMOS transistor 30 having a gate, a source and a drain. The gate of the controller 600 is coupled to an electrical reference, for example, ground, the source of the controller 600 is coupled to a voltage source V_{CC}, and the drain of the controller 600 is coupled to the transmission path 32 to match the characteristic impedance of the transmission path 32.

The dual mode data output buffer 500 may include a first driver, a second driver and a transmission gate 42. The first driver, for example, a PMOS transistor 34, and the second driver, for example, an NMOS transistor 36, are connected in series between a first electrical reference, for example, a voltage source V_{CC}, and second electrical reference, for example, ground. As illustrated in FIG. 3, a drain of the PMOS transistor 34 is coupled with a drain of the NMOS transistor 36. An input/output node 55, provided between the PMOS transistor 34 and the NMOS transistor 36, is coupled with the transmission path 32.

The dual mode data output buffer 500 may receive first and second data output signals OutP and OutN, respectively. The first and second drivers may be turned on to output data. The transmission gate 42 may be coupled to the second driver, for example, a gate of the NMOS transistor 36. The transmission gate 42 may be used to selectively switch between a first mode of operation and a second mode of operation of the dual mode data output buffer 500. The first mode may be, for example, a push-pull mode and the second mode may be, for example, an open drain mode. The transmission gate 42 may be configured to selectively operate in the first and second modes in response to the voltage source V_{CC} and/or a mode control signal, for example, a mode register set (MRS) signal, a fusing signal and/or a ground voltage V_{SS}.

As further illustrated in FIG. 3, the transmission gate 42 includes a first transistor and a second transistor. The first transistor may be, for example, an NMOS transistor 38, having a gate, a drain and a source. The gate of the NMOS transistor 38 may be coupled to a first power, for example, a voltage source V_{CC}, the drain of the NMOS transistor 38 may receive the second data output drive signal OutN and the source of the NMOS transistor 38 may be coupled to a gate of the NMOS transistor 36. The second transistor may be, for example, a PMOS transistor 40 having a gate, a source and a drain. The gate of the PMOS transistor 40 may be coupled to, for example, an MRS signal, a fusing signal and/or a second power, for example, a ground voltage V_{SS}. The drain of the PMOS transistor 40 may receive the second data output signal OutN and the source of the PMOS transistor 40 may be coupled to the gate of the NMOS transistor 36.

It will be understood that embodiments of the present invention illustrated in FIG. 3 are provided for exemplary purposes only and that embodiments of the present invention are not limited to this configuration. Many equivalent circuits may be used without departing from the teachings of the present invention. For example, the first driver may be replaced with an on die termination (ODT) element without departing from the teachings of the present invention.

Referring now to FIGS. 3 and 4, operations according to embodiments of the present invention will be discussed. FIG. 4 is a voltage waveform illustrating operations of the dual mode data output buffer when the second driver operates in a saturation region during the second mode of operation, for example, the open drain mode, according to embodiments of the present invention. A gate of the PMOS transistor 30 is coupled to a ground voltage V_{SS}, therefore the PMOS transistor 30 is normally turned on. The PMOS transistor 30 may be designed by adjusting a size such that a reciprocal number of a transconductance (gm) is the same as an impedance (Zₒ). When the PMOS transistor 30 is turned on, the voltage source V_{T} is applied to the transmission path 32.

During the first mode of operation, i.e. the push-pull mode, the first and second data output signals OutP and OutN are applied to a gate of the PMOS transistor 34 and the transmission gate 42, respectively. For example, when the first and second data output signals OutP and OutN are set to a logic high level and are respectively applied to the gate of the PMOS transistor 34 and the transmission gate 42, the PMOS transistor 34 is turned off. Furthermore, a voltage source V_{CC} is applied to the gate of the NMOS transistor 38 of the transmission gate 42. When an MRS signal, a fusing signal and/or a ground voltage V_{SS} is set to a logic low level and applied to the gate of the PMOS transistor 40 of the transmission gate 42, the NMOS transistor 38 and the PMOS transistor 40 of the transmission gate 42 are both turned on. Accordingly, when the second data output signal OutN applied to the transmission gate 42 is transmitted at a logic high level to the gate of the NMOS transistor 36 the NMOS transistor 36 is turned on. Thus, when the NMOS transistor 36 is turned on and the PMOS transistor 34 is turned off as discussed above, a signal having a logic low level is output to the transmission path 32.

In contrast, when the first and second data output signals OutP and OutN are set to a logic low level and are respectively applied to the gate of the PMOS transistor 34 and the transmission gate 42, the PMOS transistor 34 is turned on. When the voltage source V_{CC} is applied to the gate of the NMOS transistor 38 of the transmission gate 42 and the MRS signal, a fusing signal and/or the ground voltage V_{SS} having a logic low level is applied to the gate of the PMOS transistor 40 of the transmission gate 42, the NMOS transistor 38 and the PMOS transistor 40 within the transmission gate 42 are both turned on. Accordingly, the second data output signal OutN having a logic low level is applied to the transmission gate 42 and transferred to the gate of the NMOS transistor 36. Therefore, the NMOS transistor 36 is turned off and the PMOS transistor 34 is turned on as discussed above. Thus, a signal having a logic high level is output to the transmission path 32.

Accordingly, during the first mode of operation, i.e. the push-pull mode, the voltage source V_{CC} is applied to the NMOS transistor 38 turning the NMOS transistor 38 on and the MRS signal, the fusing signal and/or the ground voltage V_{SS} having a logic low level is applied to the gate of the PMOS transistor 40 turning the PMOS transistor 40 on. Thus, the second data output signal OutN is transferred to the gate of the NMOS transistor 36 without modification or loss of a threshold voltage. In other words, during the first mode of operation, the transmission gate 42 of the dual mode data output buffer 500 is transparent and the dual mode data buffer 500 operates as if the second data output signal is applied directly to the gate of the NMOS transistor 36.

During the second mode of operation, i.e. the open drain mode, the first data output signal OutP is applied at a V_{CC} level (logic high level) to the gate of the PMOS transistor 34, such that the PMOS transistor 34 is in an off state. The second data output signal OutN is applied as either a logic high level or logic low level to the transmission gate 42. The voltage source V_{CC} is applied to the gates of the NMOS transistor 38 and the PMOS transistor 40 of the transmission gate 42. Thus, the NMOS transistor 38 is turned on and the PMOS transistor 40 is turned off. Furthermore, the NMOS transistor 38 transfers a voltage equal to the second data output signal OutN decreased by a threshold voltage Vₜₕ to the gate of the NMOS transistor 36. For example, if the second data output signal OutN is equal to V_{CC} (a logic high level), a bias voltage of V_{cc}-Vₜₕ is transferred to the gate of the NMOS transistor 36. On the other hand, if the second data output signal OutN is equal to V_{SS} (a logic low level), V_{SS} is transferred to the gate of the NMOS transistor 36 without modification. Accordingly, an output swing of the general open drain system is in a range of from about V_{CC} to about V_{SS} as illustrated by A of FIG. 4. However, this signal is passed through the NMOS transistor 38 of the transmission gate 42, thus the output swing is in the range of from about V_{cc}-Vₜₕ through V_{SS} as illustrated by B of FIG. 4 and is applied to the gate of the NMOS transistor 36. Accordingly, the NMOS transistor 36 operates normally as a current mode driver at a saturation region.

During operation in the second mode, i.e. the open drain mode, the data output signal OutP is applied to the gate of the PMOS transistor 34. When the second data output signal OutP is set to a logic high level and applied to the gate of the PMOS transistor 34, the PMOS transistor 34 is turned off and the output data is set to a logic low level on the transmission path 32. In contrast, when the second data output signal OutP is set to a logic low level and applied to the gate of the PMOS transistor 34, the PMOS transistor 34 is turned on and the output data is set to a logic low level on the transmission path 32.

As briefly described above with respect to FIGS. 3 and 4, embodiments of the present invention provide first and second drivers corresponding to, for example, the PMOS transistor 34 and the NMOS transistor 36, respectively, that are configured to output data to the transmission path 32 in response to the first and second data output signals OutP and OutN, respectively. Dual mode data output buffers according to embodiments of the present invention may operate in a push-pull mode and/or an open drain mode, thus providing a single data output buffer having a dual mode of operation, which can be used in place of separate data output buffers in a single integrated circuit device. Accordingly, integrated circuit devices using dual mode data output buffers according to embodiments of the present invention may be less expensive and allow a size reduction of the integrated circuit device.

In the drawings and specification, there have been disclosed typical preferred embodiments of the invention and, although specific terms are employed, they are used in a generic and descriptive sense only and not for purposes of limitation, the scope of the invention being set forth in the following claims.

That which is claimed is:

1. A dual mode data output buffer, comprising:
first and second drivers configured to output data responsive to first and second data output signals, respectively; and
a transmission gate configured to select between a first mode of operation and a second mode of operation responsive to a mode control signal, the transmission gate providing the second data output signal to the second driver when the mode control signal is not asserted during the first mode of operation and the transmission gate providing a modified second data output signal to the second driver when the mode control signal is asserted during the second mode of operation.

2. A dual mode data output buffer according to claim 1 wherein the transmission gate comprises a first transistor that is responsive to a first electrical reference and the second data output signal and a second transistor that is responsive to the mode control signal and the second data output signal, wherein the first electrical reference is set to a logic high level during the first and second modes of operation and wherein the mode control signal is set to a logic low level during the first mode of operation and set to a logic high level during the second mode of operation.

3. A dual mode data output buffer according to claim 2 wherein the second data output signal is set to V_{CC} during the second mode of operation and is applied to the transmission gate and wherein the transmission gate transmits the second data output signal (V_{CC}) decreased by a threshold voltage (Vₜₕ) to the second driver to provide the modified second data output signal.

4. A dual mode data output buffer according to claim 3 wherein the first driver comprises a PMOS transistor and the second driver comprises and NMOS transistor.

5. A dual mode data output buffer according to claim 4 wherein the first data output signal is set to a logic high level during the second mode of operation and wherein the dual mode data output buffer provides a logic low signal to a controller over a transmission line.

6. A dual mode data output buffer according to claim 4 wherein the first data output signal is set to a logic low level during the second mode of operation and wherein the dual mode data output buffer provides a logic high signal to a controller over a transmission line.

7. A dual mode data output buffer according to claim 2 wherein the first transistor comprises an NMOS transistor and the second transistor comprises a PMOS transistor.

8. A dual mode data output buffer according to claim 1 wherein the first and second output control signals are set to a logic high level during the first mode of operation, wherein the first driver is turned off during the first mode of operation, wherein the second driver is turned on during the first mode of operation and wherein the dual mode data output buffer provides a logic low signal to a controller over a transmission line.

9. A dual mode data output buffer according to claim 1 wherein the first and second output control signals are set to a logic low level during the second mode of operation, wherein the first driver is turned on during the second mode of operation, the second driver is turned off during the second mode of operation and wherein the dual mode data output buffer provides a logic high signal to a controller over a transmission line.

10. A dual mode data output buffer according to claim 1 wherein first and second channels of the first and second drivers, respectively, are connected in series between a first electrical reference and a second electrical reference.

11. A dual mode data output buffer according to claim 1 wherein the first mode of operation is a push pull mode wherein the second mode of operation is an open drain mode.

12. A dual mode data output buffer according to claim 1 wherein the mode control signal comprises a mode register set signal, a fusing signal and/or an electrical reference.

13. A method of operating a dual mode data output buffer comprising:
applying first and second data output signals to first and second drivers, respectively;
selecting a first mode of operation of the first and second drivers and/or a second mode of operation of the first and second drivers based on a mode control signal;
providing the second data output signal to the second driver when the mode control signal is not asserted during the first mode of operation; and
providing a modified second data output signal to the second driver when the mode control signal is asserted during the second mode of operation.

14. A method according to claim 13, wherein providing the second data output signal to the second driver further comprises providing the second data output signal to the second driver when a first electrical reference is set to a logic high level and the mode control signal is set to a logic low level during the first mode of operation and wherein providing a modified second data output signal to the second driver comprises providing a modified second data output signal to the second driver when the first electrical reference is set to a logic high level during a second mode of operation and the mode control signal is set to a logic high level during the second mode of operation.

15. A method according to claim 14, further comprising:
setting the data output signal to V_{CC} during the second mode of operation; and
applying the data output signal to a transmission gate; and
transmitting the second data output signal (V_{CC}) decreased by a threshold voltage (Vₜₕ) to the second driver to provide the modified second data output signal.

16. A method according to claim 15, further comprising:
setting the first data output signal to a logic high level during the second mode of operation; and
providing a logic low signal to a controller over a transmission line.

17. A method according to claim 15, further comprising:
setting the first data output signal to a logic low level during the second mode of operation; and
providing a logic high signal to a controller over a transmission line.

18. A method according to claim 13, further comprising:
setting the first and second output control signals to a logic high level during the first mode of operation, wherein the first driver is turned off during the first mode of operation and wherein the second driver is turned on during the first mode of operation; and
providing a logic low signal to a controller over a transmission line.

19. A method according to claim 13, further comprising:
setting the first and second output control signals to a logic low level during the first mode of operation, wherein the first driver is turned on during the first mode of operation and wherein the second driver is turned off during the second mode of operation; and
providing a logic high signal to a controller over a transmission line.

20. A data output buffer including a push-pull output driver and a current mode open drain output driver, the buffer comprising:
first and second drivers having respective channels connected in series between a first power and a second power, the first and second drivers outputting data in response to first and second data output signals, respectively; and
a transmission gate coupled to the second driver that transmits the second data output signal to the second driver responsive to the first power and a mode control signal.

21. The buffer according to claim 20, wherein the mode control signal is a mode register set signal, a fusing signal and/or the second power.

22. The buffer according to claim 21, wherein the first driver is a PMOS transistor and wherein the second driver is an NMOS transistor.

23. The buffer according to claim 22, wherein the transmission gate comprises:
a first transistor that is driven by the first power supplied to a gate of the first transistor, receives the second data output signal at a drain of the first transistor, and transfers the second data output signal to the second driver through a source of the first transistor when operating in the push-pull data output buffer mode, wherein the first transistor is driven by the first power supplied to the gate of the first transistor, receives the second data output signal, and transfers the second data output signal to the second driver through the source of the transistor, when operating in the current mode open drain data output buffer mode; and
a second transistor that is driven by a mode register set signal supplied to a gate of the second transistor, receives the second data output signal through a drain of the second transistor, and transfers the second data output signal to the second driver through a source of the second transistor, when operating in the push-pull type data output buffer mode, wherein the second transistor receives the second data output signal through the drain of the second transistor, by using the first power supplied to the gate of the second transistor, so as not to transfer the second data output signal to the second driver through the source, when operating in the current mode open drain data output buffer mode.

24. The buffer according to claim 23, wherein the first transistor is an NMOS transistor and where the second transistor is a PMOS transistor.

25. A data output buffer including an push-pull output driver and a current mode open drain output driver, the buffer comprising:
first and second drivers connected in series between a first power and a second power that receive first and second data output signals, respectively, and output data; and
a transmission gate coupled with the second driver, for individually receiving the first power and a mode control signal and selectively operating one of the push-pull output driver and the current mode open drain output driver.

26. The buffer according to claim 25, wherein the mode control signal is a mode register set signal, a fusing signal and/or the second power.

27. The buffer according to claim 26, wherein the first driver is a PMOS transistor and the second driver is an NMOS transistor.

28. The buffer according to claim 27, wherein said transmission gate comprises:
a first transistor that is driven by the first power supplied to a gate of the first transistor, receives the second data output signal at a drain of the first transistor, and transfers the second data output signal to the second driver through a source of the first transistor when operating in the push-pull data output buffer mode, wherein the first transistor is driven by the first power supplied to the gate of the first transistor, receives the second data output signal, and transfers the second data output signal to the second driver through the source of the transistor, when operating in the current mode open drain data output buffer mode; and
a second transistor that is driven by a mode register set signal supplied to a gate of the second transistor, receives the second data output signal through a drain of the second transistor, and transfers the second data output signal to the second driver through a source of the second transistor, when operating in the push-pull type data output buffer mode, wherein the second transistor receives the second data output signal through the drain of the second transistor, by using the first power supplied to the gate of the second transistor, so as not to transfer the second data output signal to the second driver through the source, when operating in the current mode open drain data output buffer mode.

29. The buffer according to claim 28, wherein the first transistor is an NMOS transistor and the second transistor is a PMOS transistor.

30. A data output buffer including a push-pull output driver and a current mode open drain output driver, the buffer comprising:
first and second drivers connected in series between a current source and a ground, that respectively receive first and second data output signals and output data responsive to the first and second data output signals; and
a transmission gate that is responsive to a first power and a mode control signal to transfer the second data output signal to the second driver, when operating in the push-pull output driver mode, wherein the transmission gate is configured to drop the second data output signal by a threshold voltage responsive to the first power and transfer the signal to the second driver, when operating in the current mode open drain output driver mode.

31. The buffer according to claim 30, wherein the mode control signal is a mode register set signal, a fusing signal and/or the second power.

32. The buffer according to claim 31, wherein the first driver is a PMOS transistor and the second driver is an NMOS transistor.

33. The buffer according to claim 32, wherein the transmission gate comprises:
a first transistor that is driven by the first power supplied to a gate of the first transistor, receives the second data output signal at a drain of the first transistor, and transfers the second data output signal to the second driver through a source of the first transistor when operating in the push-pull data output buffer mode, wherein the first transistor is driven by the first power supplied to the gate of the first transistor, receives the second data output signal, and transfers the second data output signal to the second driver through the source of the transistor, when operating in the current mode open drain data output buffer mode; and
a second transistor that is driven by a mode register set signal supplied to a gate of the second transistor, receives the second data output signal through a drain of the second transistor, and transfers the second data output signal to the second driver through a source of the second transistor, when operating in the push-pull type data output buffer mode, wherein the second transistor receives the second data output signal through the drain of the second transistor, by using the first power supplied to the gate of the second transistor, so as not to transfer the second data output signal to the second driver through the source, when operating in the current mode open drain data output buffer mode.

34. The buffer according to claim 33, wherein the first transistor is an NMOS transistor and the second transistor is a PMOS transistor.

35. A method of outputting data in an integrated circuit memory device that includes first and second drivers connected in series between a voltage source and a ground and respectively receive first and second data output signals and output data, and that use an push-pull output driver and a current mode open drain output driver, the method:
driving the first and second drivers in response to the first and second data output signals, respectively;
outputting the data, when operated by the push-pull output driver; and dropping the second data output signal by a threshold voltage when the first driver is turned off and the second driver is configured to operate as a current driver at a saturation region, when operated by the current mode open drain output driver.
